(19) United States
(12) Patent Application Publication
(10) Pub. No.: US 2014/0325105 A1
(43) Pub. Date: Oct. 30, 2014

(54) MEMORY SYSTEM COMPONENTS FOR SPLIT CHANNEL ARCHITECTURE

(71) Applicant: ADVANCED MICRO DEVICES, INC., Sunnyvale, CA (US)

(72) Inventors: Edoardo Prete, Arlington, MA (US); Anwar Kashem, Cambridge, MA (US); Brian Amick, Bedford, MA (US)

(73) Assignee: Advanced Micro Devices, Inc., Sunnyvale, CA (US)

(21) Appl. No.: 13/871,437

(22) Filed: Apr. 26, 2013

(51) Int. Cl. H01L 23/538; G06F 13/16

(52) U.S. Cl. CPC H01L 23/538; G06F 13/1642
USPC 710/112; 257/786

(57) ABSTRACT

In one form, a memory module includes a first plurality of memory devices comprising a first rank and having a first group and a second group, and first and second chip select conductors. The first chip select conductor interconnects chip select input terminals of each memory device of the first group, and the second chip select conductor interconnects chip select input terminals of each memory device of the second group. In another form, a system includes a memory controller that performs a first burst access using both first and second portions of a data bus and first and second chip select signals in response to a first access request, and a second burst access using a selected one of the first and second portions of the data bus and a corresponding one of the first and second chip select signals in response to a second access request.

### FIELD

This disclosure relates generally to computer memory systems, and more specifically to computer memory system components capable of performing burst accesses.

### BACKGROUND

Memory channels in modern high performance computer systems are commonly 64-bits wide and commonly operate with a burst length of eight to support 512-bit burst transactions. Memory systems at certain times have a need for transactions of different sizes (e.g., 256-bit transactions), for example for applications such as graphics or video playback. Modern Double Data Rate (DDR) memories address this need by providing a “burst chop” mode. While the burst chop mode allows accesses of one size to be mixed with accesses of another size without having to put the memory into the precharge all state to change the setting in the mode register, it still requires some overhead.

### BRIEF DESCRIPTION OF THE DRAWINGS

FIG. 1 illustrates in block diagram form a memory system known in the prior art;

FIG. 2 illustrates a timing diagram of the memory system of FIG. 1 during a burst chop operation known in the prior art;

FIG. 3 illustrates in block diagram form a memory system according to some embodiments;

FIG. 4 illustrates a top view of a dual inline memory module (DIMM) that can be used to implement the memory of FIG. 3 according to some embodiments;

FIG. 5 illustrates a table showing the burst order and data pattern for a burst access to the memory of FIG. 3 having a first size according to some embodiments;

FIG. 6 illustrates a table showing the burst order and data pattern for a burst access to the memory of FIG. 3 having a second size according to some embodiments;

FIG. 7 illustrates a table showing the burst order and data pattern for a burst access to the memory of FIG. 3 having the second size according to some embodiments;

FIG. 8 illustrates a table showing the burst order and data pattern for a burst access to the memory 340 of FIG. 3 having the second size according to some embodiments;

FIG. 9 illustrates in block diagram form a data processor according to some embodiments; and

FIG. 10 illustrates a flow diagram of a method for accessing memory according to some embodiments.

In the following description, the use of the same reference numerals in different drawings indicates similar or identical items. Unless otherwise noted, the word “coupled” and its associated verb forms include both direct connection and indirect electrical connection by means known in the art, and unless otherwise noted any description of direct connection implies alternate embodiments using suitable forms of indirect electrical connection as well.

### DETAILED DESCRIPTION OF ILLUSTRATIVE EMBODIMENTS

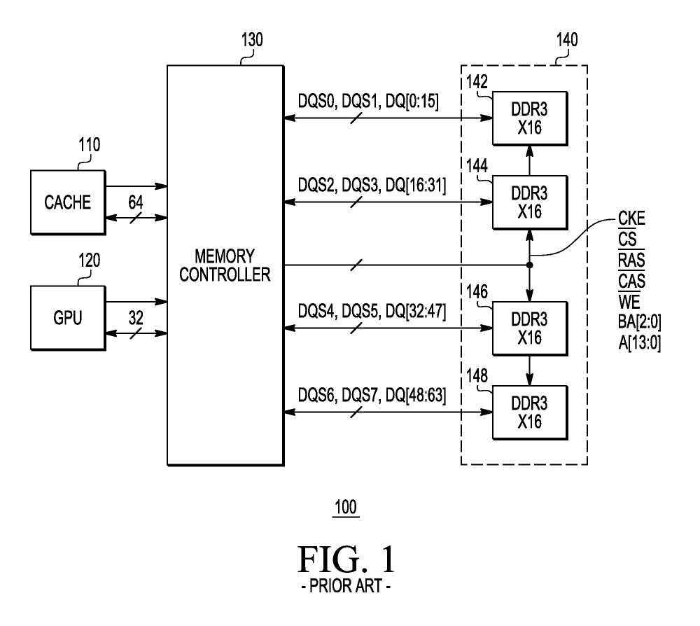

FIG. 1 illustrates in block diagram form a memory system 100 known in the prior art. Memory system 100 generally includes a cache 110, a graphics processing unit (GPU) 120, a memory controller 130, and a memory 140. Memory 140 includes four by-sixteen (×16) double data rate type three (DDR3) memory chips 142, 144, 146 and 148. Cache 110 has an output for providing address and control signals for memory transactions to memory 140 via memory controller 130, and has a 64-bit bidirectional data port for sending write data to or receiving read data from the memory system via memory controller 130. GPU 120 has an output for providing address and control signals for memory transactions to memory 140 via memory controller 130, but has a 32-bit bidirectional data port for sending write data to or receiving read data from the memory system via memory controller 130.

Memory controller 130 has a first request port connected to cache 110, a second request port connected to GPU 120, and a response port connected to memory 140. The first request port has an input connected to the output of cache 110, and a bidirectional data port connected to the bidirectional data port of cache 110. The second request port has an input connected to the output of GPU 120, and a bidirectional data port connected to the bidirectional data port of GPU 120. The response port has an output for providing a set of command and address signals, and a bidirectional data port for sending write data and data strobe signals to, or receiving read data and data strobe signals from, memory 140.

Memory 140 is connected to the response port of memory controller 130 and has an input connected to the output of the response port of memory controller 130, and a bidirectional data port connected to the bidirectional data portion of the response port of memory controller 130. In particular, memory chips 142, 144, 146, and 148 of memory 140 are connected to respective data and data strobe portions of the response port of memory controller 130, but have inputs connected to all of the command and address outputs of the response port of memory controller 130. Thus memory chip 142 conducts data signals DQ[0:15] and data strobe signals DQS0 and DQS1 to and from memory controller 130; memory chip 144 conducts data signals DQ[16:31] and data strobe signals DQS2 and DQS3 to and from memory controller 130; memory chip 146 conducts data signals DQ[32:47] and data strobe signals DQS4 and DQS5 to and from memory controller 130; and memory chip 148 conducts data signals DQ[48:63] and data strobe signals DQS6 and DQS7.

In the case of DDR3 SDRAM, pertinent command signals include a clock enable signal labeled “CKE”, a chip select labeled “ C̅S̅”, a row address strobe signal labeled “ R̅A̅S̅”, a column access strobe labeled “ C̅A̅S̅”, and a write enable signal labeled “ W̅E̅”. Pertinent address signals include a bank address bus labeled “BA[2:0]”, and a set of address signals labeled “A[13:0]”.

Memory 140 has a 64-bit data bus broken into four 16-bit segments and a command/address bus routed in common between all memory chips. For a burst of length of eight, 64 bits are transferred each bus cycle, or beat, and a total of 64 bytes (512 bits) are transferred during an 8-bit burst. Cache 110 has a 64-byte cache line and memory controller 130 can perform a cache line fill or a writeback of a complete cache line during one 8-beat burst of memory 140.

Other circuit blocks, however, have natural data sizes different than 512 bits. For example, GPU 120 has a 32-bit interface and accesses 32 bytes (256 bits) of data at a time. In order to accommodate both burst lengths efficiently, DDR3 memory chips support a “burst chop” cycle, during which the memory chips transfer only 256 bits of data during a burst. The change in the burst size takes place “on the fly”, so that the normal burst length of eight is not affected and the memory does not need to be placed in the precharge all state to re-write the burst length setting in the mode register. During a burst chop cycle, all memory chips access their data. For example, since DDR3 memory uses an “8n-bit” prefetch architecture, 512 bits of data are typically accessed from the array even though only 256 bits are supplied.

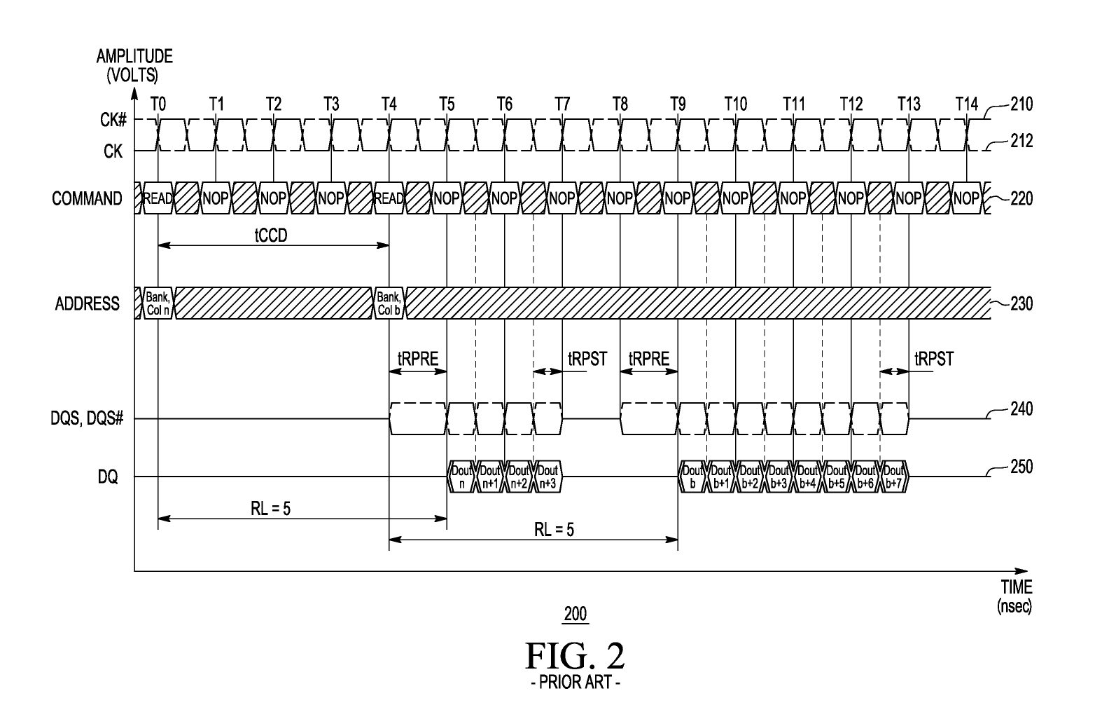

FIG. 2 illustrates a timing diagram 200 of memory system 100 of FIG. 1 during a burst chop operation known in the prior art. In FIG. 2, the horizontal axis represents time in nanoseconds (nsec), whereas the vertical axis represents the amplitude of various signals in volts. FIG. 2 illustrates several waveforms of interest, including a true clock (CK) waveform labeled “CK” 210, a complementary clock ( C̅K̅) waveform 212, a command waveform 220, an address waveform 230, a data strobe waveform 240, and a data (DQ) waveform 250. CK and C̅K̅ 212 are differential clock inputs to memory 140. FIG. 2 also illustrates several points in time, aligned with the rising edge of the CK signal, labeled “T0” through “T14”.

In operation, memory controller 130 encodes commands, including READ and WRITE commands, on the C̅S̅, R̅A̅S̅, C̅A̅S̅, and W̅E̅ command signals. As shown in FIG. 2, memory controller 130 outputs a READ command on the command signals that memory 140 detects on the rising edge of the CK signal at time T0, to the bank indicated by the BA[2:0] signals, and to a memory location in the selected bank indicated by the A[13:0] signals. As shown in FIG. 2, memory controller 130 indicates that the READ cycle is a READ with a burst chop of 4 by additionally encoding a burst chop signal on address signal A12 that it provides coincident with the READ command. After a certain delay defined by a programmable parameter known as the read latency (RL), each memory chip drives its corresponding DQS signals low at time T4 to start a preamble phase, after which it drives the first data labeled “D_{OUT} n” at the rising edge of its corresponding DQS signals at time T5. Since this read cycle is a burst chop cycle, each memory chip provides additional data elements labeled “D_{OUT} n+1”, “D_{OUT} n+2”, and “D_{OUT} n+3” on successive falling and rising edges of its corresponding DQS signals until it provides a total of four data elements (a total of 256 data bits).

Memory controller 130 outputs a subsequent READ command having a burst length of 8 (the value programmed in the mode register) at time T4. However since the burst chop command does not affect the programmed burst length of 8, it cannot recognize the subsequent READ with a burst length of 8 until a time labeled “t_{CCD}” has elapsed, and the subsequent READ does not begin until after read latency of 5 clock cycles after receipt of the command. At that point, the memory outputs the eight data elements in succession starting at time T9.

While the burst chop mode saves a significant amount of time that would have been used to precharge all banks, perform a write cycle to the mode register, and reactivate the rows in all active banks, it still requires dead time in between the rising edges of times T7 and T9. During this time the memory chips remain active since the internal memory array and control circuitry still operate according to a burst length of 8. Thus memory controller 130 causes all DRAMs to consume power during the unused four cycles of the chopped burst.

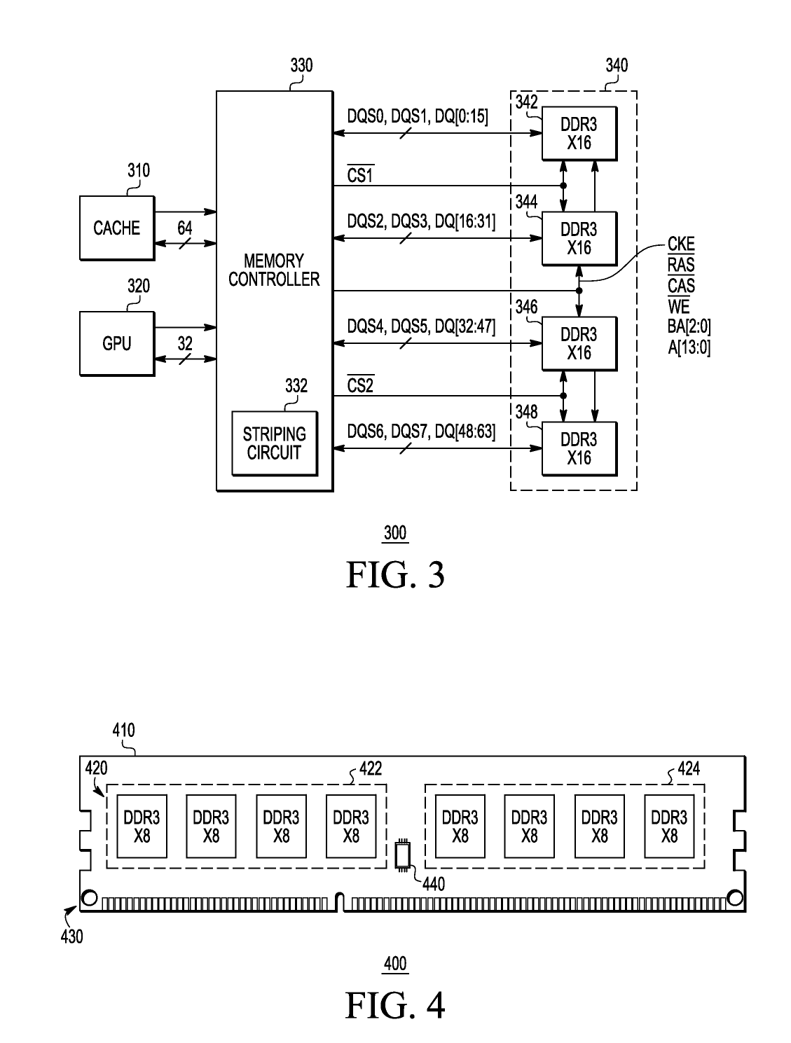

FIG. 3 illustrates in block diagram form a memory system 300 according to some embodiments. Memory system 300 generally includes a cache 310, a GPU 320, a memory controller 330, and a memory 340. Memory 340 generally includes four x16 DDR3 DRAMs 342, 344, 346 and 348 implemented as separate memory chips. In some embodiments, other types of memory chips such as double data rate type four (DDR4) may be utilized. Cache 310 has an output for providing address and control signals for memory transactions to memory 340 via memory controller 330, and has a 64-bit bidirectional port for sending write data to or receiving read data from the memory system via memory controller 130. GPU 320 has an output for providing address and control signals for memory transactions to memory 340 via memory controller 330, but has a 32-bit bidirectional port for sending write data to or receiving read data from the memory system via memory controller 330.

Memory controller 330 has a first request port connected to cache 310, a second request port connected to GPU 320, and a response port connected to memory 340. The first request port has an input connected to the output of cache 310, and a bidirectional port connected to the bidirectional port of cache 310. The second request port has an input connected to the output of GPU 320, and a bidirectional port connected to the bidirectional port of GPU 320. The response port has an output for providing as set of address and control signals, and a bidirectional port for sending write data and data strobe signals to, or receiving read data and data strobe signals from, memory 340. Memory controller 330 also includes a striping circuit 332, which provides two chip select signals labeled “ C̅S̅1̅” and “ C̅S̅2̅” for one rank of memory. The features and operation of striping circuit 332 will be described further below.

Memory 340 is connected to the response port of memory controller 330 and has an input connected to the output of the response port of memory controller 330, and a bidirectional data port connected to the bidirectional port of the response port of memory controller 330. In particular, DRAMs 342, 344, 346, and 348 of memory 340 are connected to respective portions of the data and data strobe bus of the response port of memory controller 130. Thus memory chip 142 conducts data signals DQ[0:15] and data strobe signals DQS0 and DQS1 to and from memory controller 130; memory chip 144 conducts data signals DQ[16:31] and data strobe signals DQS2 and DQS3 to and from memory controller 130; memory chip 146 conducts data signals DQ[32:47] and data strobe signals DQS4 and DQS5 to and from memory controller 130; and memory chip 148 conducts data signals DQ[48:63] and data strobe signals DQS6 and DQS7.

Each memory chip has inputs connected to all of the command and address outputs of the response port of memory controller 130, except that DRAMs 342 and 344 both receive signal C̅S̅1̅, and DRAMs 346 and 348 both receive signal C̅S̅2̅. Note that memory 340 uses by-16 (x16) memory chips 342, 344, 346, and 348 organized into a first group (memory chips 342 and 344) receiving chip select signal C̅S̅1̅, and a second group (memory chips 346 and 348) receiving signal C̅S̅2̅. In some embodiments, memory 340 could use one x32 memory chip in a group, four x8 memory chips in a group, or eight x4 memory chips in a group.

In operation, memory controller 330 receives access requests from two memory accessing agents, cache 310 and GPU 320. Cache 310 generates READ and WRITE requests that correspond to 512-bit cache line fills and 512-bit cache line writebacks, respectively. Thus for a 64-bit memory chip, cache 310 performs bursts of 8 to fetch or store 512 bits of data. On the other hand, GPU 320 generates READ and WRITE requests that correspond to 256-bit graphics accesses such as AGP transactions.

Memory controller 330 includes striping circuit 332 to avoid the power required for burst chop cycles when performing 256-bit accesses. Striping circuit 332 allows memory controller 330 to alternately perform a burst access of eight on one half of the bus by activating the corresponding chip select signal signals while keeping the other memory chips inactive, and then to perform a burst access of eight on the other half of the bus by selecting the alternate chip select signals while keeping the original memory chips inactive. To implement striping to facilitate power reduction, memory 340 includes an extra signal line for the new chip select signal. Moreover the data will be stored and retrieved differently in memory, in a manner which will be described below.

FIG. 4 illustrates a top view of a dual inline memory module (DIMM) 400 that can be used to implement memory 340 of FIG. 3 according to some embodiments. DIMM 400 generally includes a substrate 410, a set of memory chips 420, an edge connector 430, and a serial presence detect (SPD) chip 440. In some embodiments, substrate 410 is a multi-layer printed circuit board (PCB). Memory chips 420 include two groups of four x8 memory chips, i.e., a memory chip group 422 and a memory chip group 424. In some embodiments, memory chips 420 are DDR3 SDRAMs. In some embodiments, memory chips 420 are DDR4 SDRAMs. Edge connector 430 generally includes pins for command and address busses, data buses and the like, but also includes two chip select pins, C̅S̅1̅ for memory chip group 422 and C̅S̅2̅ for memory chip group 424.

It should be noted that in some embodiments, DIMM 400 could have a second set of memory devices on the back of the substrate 410, arranged like memory chips 420 into groups with each group having its own corresponding chip select signal. The edge connector in this case would also include two chip select pins on the back side. In some embodiments, each memory chip can include a semiconductor package having multiple memory die, using chip-on-chip or stacked die technology, to form more than one rank per chip.

Moreover DIMM 400 is representative of the types of memory which could be used to implement memory 340 of FIG. 3. In some embodiments, memory 340 could be implemented by a single inline memory module (SIMM), or with memory chips mounted on the same PCB as memory controller 330.

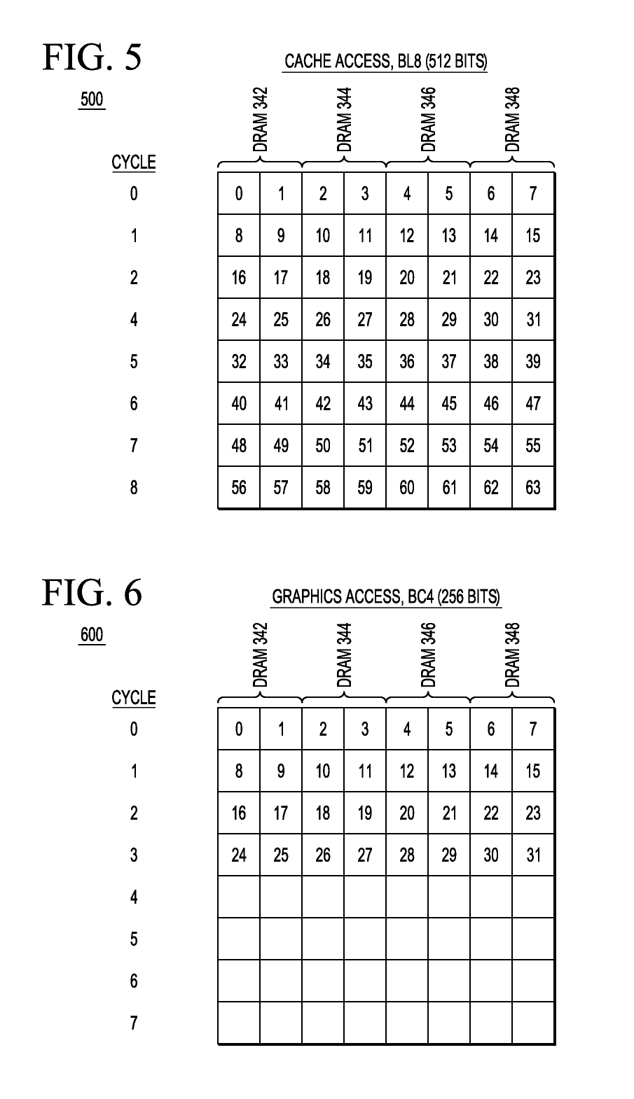

FIG. 5 illustrates a table 500 showing the burst order and data pattern for a burst access to memory 340 of FIG. 3 having a first size according to some embodiments. In FIG. 5, the burst is a cache line access having a size of 512 bits with a burst length of 8 (BL8). Table 500 illustrates the location of data bytes in DRAMs 342, 344, 346 and 348. In table 500, the columns represent particular memory chips, whereas the rows represent different beats of a burst of length 8. Memory controller 330 initiates this burst access by activating both C̅S̅1̅ and C̅S̅2̅ and providing the other control signals to indicate a READ or WRITE burst of length 8. After a time defined by the read or write latency, memory controller 330 accesses bytes 0 and 1 in DRAM 342, bytes 2 and 3 in DRAM 344, and so forth. In cycle 1, memory controller 330 accesses bytes 8 and 9 in DRAM 342, bytes 10 and 11 in DRAM 344, and so forth. The pattern repeats as shown until in cycle 7, memory controller 330 accesses bytes 62 and 63 in DRAM 348.

FIG. 6 illustrates a table 600 showing the burst order and data pattern for a burst access to memory 340 of FIG. 3 having a second size according to some embodiments. In FIG. 6, the burst is a graphics access having a size of 256 bits with a burst chopped to 4 (BC4). As in table 500, table 600 illustrates the location of data bytes in DRAMs 342, 344, 346 and 348. In table 600, the columns represent particular memory chips, whereas the rows represent different beats of a burst chopped to 4. Memory controller 330 initiates this burst access by activating both C̅S̅1̅ and C̅S̅2̅ and providing the other control signals to indicate a READ or WRITE burst chopped to 4. After a time defined by the read or write latency, memory controller 330 accesses bytes 0 and 1 in DRAM 342, bytes 2 and 3 in DRAM 344, and so forth. In cycle 1, memory controller 330 accesses bytes 8 and 9 in DRAM 342, bytes 10 and 11 in DRAM 344, and so forth. The pattern repeats as shown until in cycle 3, memory controller 330 accesses bytes 30 and 31 in DRAM 348.

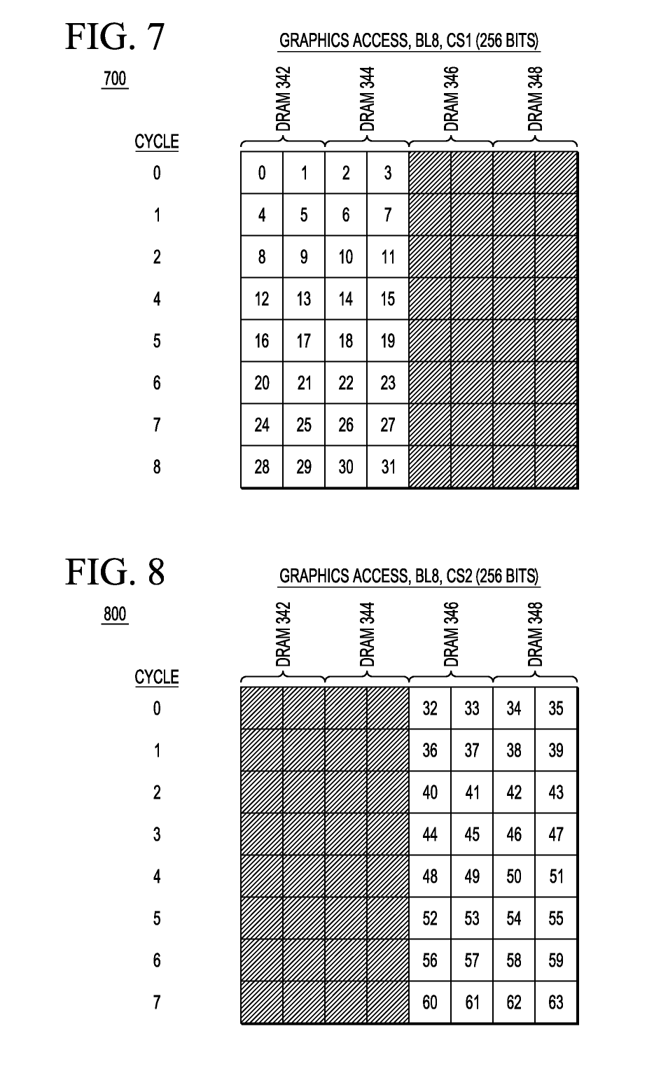

FIG. 7 illustrates a table 700 showing the burst order and data pattern for a burst access to memory 340 of FIG. 3 having the second size according to some embodiments. In FIG. 7, the burst is a graphics access having a size of 256 bits with a burst length of 8 aligned to an even 32-byte boundary. Table 700 illustrates the location of data bytes in DRAMs 342, 344, 346 and 348. In table 700, the columns represent particular memory chips, whereas the rows represent different beats of a burst of length 8 for a 32-byte set of data aligned on a 64-byte boundary. Memory controller 330 initiates this burst access by activating C̅S̅1̅ while keeping C̅S̅2̅ inactive and providing the other control signals to indicate a READ or WRITE burst of length 8. After a time defined by the read or write latency, memory controller 330 accesses bytes 0 and 1 in DRAM 342 and bytes 2 and 3 in DRAM 344. Memory controller 330 does not access any of the 32 bytes of data in DRAMs 346 and 348. In cycle 1, memory controller 330 accesses bytes 4 and 5 in DRAM 342 and bytes 6 and 7 in DRAM 344. The pattern repeats as shown until in cycle 7, memory controller 330 accesses bytes 30 and 31 in DRAM 344. For this 32-byte aligned access, memory controller 330 keeps DRAMs 346 and 348 inactive throughout the burst, saving power that would otherwise have been consumed in all four memory chips during a burst chopped to 4. Moreover, memory controller 330 does not consume any additional bandwidth, since the burst ends at the same time as for a burst chop of four.

FIG. 8 illustrates a table 800 showing the burst order and data pattern for a burst access to memory 340 of FIG. 3 having the second size according to some embodiments. In FIG. 8, the burst is a graphics access having a size of 256 bits with a burst length of 8 aligned to an odd 32-byte boundary. Table 800 illustrates the location of data bytes in DRAMs 342, 344, 346 and 348. In table 800, the columns represent particular memory chips, whereas the rows represent different beats of a burst of length 8. Memory controller 330 initiates this burst access by activating C̅S̅2̅ while keeping C̅S̅1̅ inactive and providing the other control signals to indicate a READ or WRITE burst of length 8. After a time defined by the read or write latency, memory controller 330 accesses bytes 32 and 33 in DRAM 346 and bytes 34 and 35 in DRAM 348. Memory controller 330 does not access any of the 32 bytes of data in DRAMs 342 and 344. In cycle 1, memory controller 330 accesses bytes 36 and 37 in DRAM 346 and bytes 38 and 39 in DRAM 348. The pattern repeats as shown until in cycle 7, memory controller 330 accesses bytes 62 and 63 in DRAM 348. For this non 32-byte aligned access, memory controller 330 keeps DRAMs 342 and 344 inactive throughout the burst, saving power that would otherwise have been consumed in all four memory chips during a burst chopped to 4. Moreover, memory controller 330 does not consume any additional bandwidth, since the burst ends at the same time as for a burst chop of four.

Note that the two 256-bit accesses to the two halves of the channel illustrated in FIGS. 7 and 8 can partially overlap in time, because they have different addresses.

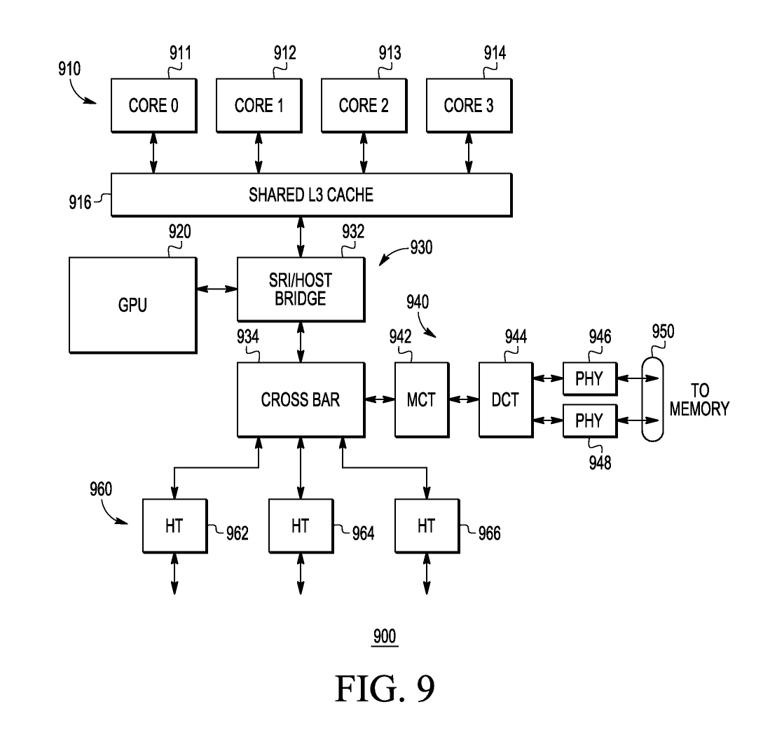

FIG. 9 illustrates in block diagram form a data processor 900 according to some embodiments. Data processor 900 generally includes a CPU portion 910, a GPU 920, an interconnection circuit 930, a memory access controller 940, a memory interface 950 and an input/output controller 960.

CPU portion 910 includes CPU cores 911-914 labeled “CORE0”, “CORE1”, “CORE2”, and “CORE3”, respectively, and a shared level three (L3) cache 916. Each CPU core is capable of executing instructions from an instruction set and may execute a unique program thread. Each CPU core includes its own level one (L1) and level two (L2) caches, but shared L3 cache 916 is common to and shared by all CPU cores. Shared L3 cache 916 corresponds to cache 310 in FIG. 3 and operates as a memory accessing agent to provide memory access requests including memory read bursts for cache line fills and memory write bursts for cache line writebacks. L3 cache 916 has a cache line size of 512 bits and thus provides line fill and writeback requests having a size of 512 bits.

GPU 920 is an on-chip graphics processing engine and also operates as a memory accessing agent. GPU 920 provides memory access requests having a size of 256 bits.

Interconnection circuit 930 generally includes system request interface (SRI)/host bridge 932 and a crossbar 934. SRI/host bridge 932 queues access requests from shared L3 cache 916 and GPU 920 and manages outstanding transactions and completions of those transactions. Crossbar 934 is a crosspoint switch between its five bidirectional ports, one of which is connected to SRI/host bridge 932.

Memory access controller 940 has a bidirectional port connected to crossbar 934 and a memory interface 950 for connection to two channels of off-chip DRAM. Memory access controller 940 generally includes a memory controller 942 labeled “MCT”, a DRAM controller 944 labeled “DCT”, and two physical interfaces 946 and 948 each labeled “PHY”. Memory controller 942 generates specific read and write transactions for requests from CPU cores 911-914 and GPU 920 and combines transactions to related addresses. DRAM controller 944 handles the overhead of DRAM initialization, refresh, opening and closing pages, grouping transactions for efficient use of the memory bus, and the like. Physical interfaces 946 and 948 provide independent channels to different external DRAMs, such as different DIMMs, and manage the physical signaling. Together DRAM controller 944 and physical interfaces 946 and 948 support at least one particular memory type, such as both DDR3 and DDR4. In some embodiments, memory access controller 940 implements the functions of memory controller 330 of FIG. 3 as described above.

Input/output controller 960 includes three high speed interface controllers 962, 964, and 966 each labeled “HT” because they comply with the HyperTransport link protocol.

It should be apparent that data processor 900 is an example of a modern multi-core data processor that memory controller 330 of FIG. 3 could be used. In some embodiments, CPU core portion 910 could have a different number of CPU cores, could have one CPU core, could have a different cache architecture, etc. In some embodiments, data processor 900 could have another memory accessing agent with a different burst size instead of or in addition to GPU 920. In some embodiments, a data processor could have a memory access controller with a different architecture than memory access controller 940.

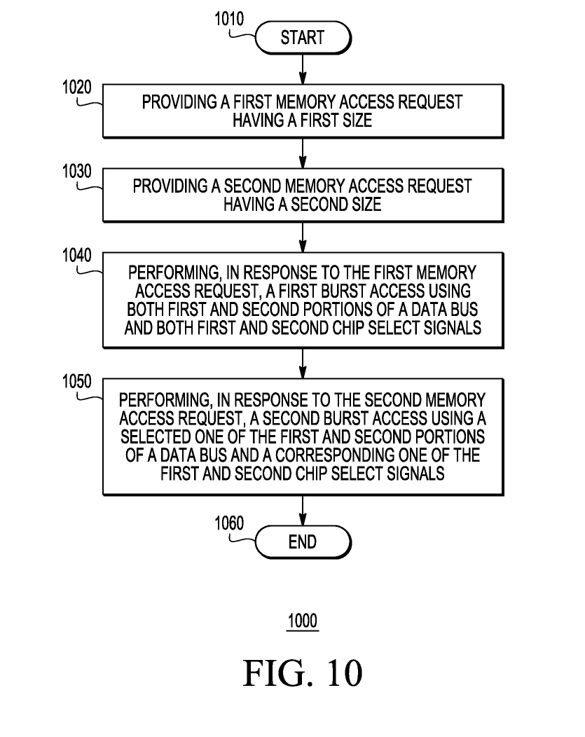

FIG. 10 illustrates a flow diagram 1000 of a method for accessing memory according to some embodiments. Method 1000 start at box 1010. An action box 1020 including providing a first memory access request having a first size. For example, a memory accessing agent such as cache 310 of FIG. 3 provides a cache line fill request having a size of 512 bits. Action box 1030 includes providing a second memory access request having a second size. For example, a memory accessing agent such as GPU 320 of FIG. 3 provides a graphics port read request having a size of 256 bits. Action box 1040 includes performing, in response to the first memory access request, a first burst access using both first and second portions of a data bus and first and second chip select signals. For example, memory controller 330 performs a burst of 8 using both the upper and lower 32-bit halves of the data bus and activates both C̅S̅1̅ and C̅S̅2̅ in response to the cache line fill request from cache 310. Action box 1050 includes performing, in response to the second memory access request, a second burst access using a selected one of the first and second portions of the data bus and a corresponding one of the first and second chip select signals. For example, memory controller 330 performs a burst of 8 using either the upper 32-bit half or the lower 32-bit half of the data bus and activates the corresponding one of C̅S̅1̅ and C̅S̅2̅ in response to a graphics port read request from GPU 320. The upper half or lower half of the data bus is selected based on whether the access is aligned to an even or off 32-byte boundary. Method 1000 ends at box 1060.

The memory controller and memory accessing agents described above may be implemented with various combinations of hardware and software. Some of the software components may be stored in a computer readable storage medium for execution by at least one processor. Moreover the method illustrated in FIG. 10 may also be governed by instructions that are stored in a computer readable storage medium and that are executed by at least one processor. Each of the operations shown in FIG. 10 may correspond to instructions stored in a non-transitory computer memory or computer readable storage medium. In various embodiments, the non-transitory computer readable storage medium includes a magnetic or optical disk storage device, solid-state storage devices such as Flash memory, or other non-volatile memory device or devices. The computer readable instructions stored on the non-transitory computer readable storage medium may be in source code, assembly language code, object code, or other instruction format that is interpreted and/or executable by one or more processors.

Moreover, the circuits illustrated above, or integrated circuits these circuits such as data processor 900 or an integrated circuit including data processor 900, may be described or represented by a computer accessible data structure in the form of a database or other data structure which can be read by a program and used, directly or indirectly, to fabricate integrated circuits with the circuits described above. For example, this data structure may be a behavioral-level description or register-transfer level (RTL) description of the hardware functionality in a high level design language (HDL) such as Verilog or VHDL. The description may be read by a synthesis tool which may synthesize the description to produce a netlist comprising a list of gates from a synthesis library. The netlist comprises a set of gates which also represent the functionality of the hardware comprising integrated circuits. The netlist may then be placed and routed to produce a data set describing geometric shapes to be applied to masks. The masks may then be used in various semiconductor fabrication steps to produce the integrated circuits. Alternatively, the database on the computer accessible storage medium may be the netlist (with or without the synthesis library) or the data set, as desired, or Graphic Data System (GDS) II data.

While particular embodiments have been described, modification of these embodiments will be apparent to one of ordinary skill in the art. For example data processor 900 could be formed by a variety of elements including additional processing units, one or more Digital Signal Processing (DSP) units, additional memory controllers and PHY interfaces and the like.

Accordingly, it is intended by the appended claims to cover all modifications of the disclosed embodiments that fall within the scope of the disclosed embodiments.

What is claimed is:

1. A memory module comprising:
a first plurality of memory devices comprising a first rank, said first plurality of memory devices including a first group and a second group;
a first chip select conductor and a second chip select conductor; and
wherein said first chip select conductor interconnects chip select input terminals of each memory chip of said first group, and said second chip select conductor interconnects chip select input terminals of each memory chip of said second group.

2. The memory module of claim 1, further comprising a substrate, wherein said first plurality of memory devices are mounted on said substrate, and said substrate includes an edge connector with pins for said first and second chip select conductors.

3. The memory module of claim 2, wherein:
the memory module comprises a second plurality of memory devices mounted on said substrate and comprising a second rank, said second plurality of memory devices including a third group and a fourth group;
the memory module comprises a third chip select conductor and a fourth chip select conductor; and
wherein said substrate couples said third chip select conductor with chip select input terminals of each memory device of said third group, and said fourth chip select conductor with chip select input terminals of each memory device of said fourth group.

4. The memory module of claim 2, wherein:
each of the first plurality of memory devices comprises a single semiconductor package and first and second semiconductor die corresponding to said first rank and a second rank, respectively;
said first semiconductor die of each memory device receives a corresponding one of said first and second chip select signals;
the memory module comprises a third chip select conductor and a fourth chip select conductor, said substrate couples said third chip select conductor with chip select input terminals of each memory chip of said first group, and said fourth chip select conductor with chip select input terminals of each memory chip of said second group; and
said second semiconductor die of each memory device receives a corresponding one of said third and fourth chip select signals.

5. The memory module of claim 1, wherein said first plurality of memory devices comprise a plurality of double data rate (DDR) memory chips.

6. The memory module of claim 5, wherein said first plurality of memory devices are substantially compatible with the JEDEC Solid State Technology Association DDR3 standard.

7. The memory module of claim 1, wherein each of said first group and said second group comprise four memory devices each having eight data terminals.

8. The memory module of claim 1, wherein the memory module is a dual inline memory module (DIMM).

9. A system comprising:
a memory controller comprising:
an input for receiving a selected one of a first access request having a first size and a second access request having a second size smaller than said first size;
a first output terminal for providing a first chip select signal;
a second output terminal for providing a second chip select signal;
a data bus interface having first and second portions;
wherein in response to said first access request, said memory controller performs a first burst access using both said first and second portions of said data bus interface and said first and second chip select signals; and
in response to said second access request, said memory controller performs a second burst access using a selected one of said first and second portions of said data bus interface and a corresponding one of said first and second chip select signals.

10. The system of claim 9, wherein said first size comprises 512 bits.

11. The system of claim 10, wherein said second size comprises 256 bits.

12. The system of claim 10, wherein said memory controller further comprises:
a striping circuit, for performing alternately performing first burst accesses using said first chip select signal and said first portion of said data bus, and second burst accesses using said second chip select signal and said second portion of said data bus, according to a predetermined pattern.

13. The system of claim 9, further comprising:
a data bus having first and second portions respectively coupled to said first and second portions of said data bus interface.

14. The system of claim 13, further comprising:
a memory module including a first chip select conductor for receiving said first chip select signal and a second chip select conductor for receiving said second chip select signal.

15. A data processor comprising:
a first memory accessing agent for providing a first memory access request having a first size;
a second memory accessing agent for providing a second memory access request having a second size;
an interconnection circuit having a first port coupled to said first memory accessing agent, a second port coupled to said second memory accessing agent, and a third port;
a memory access controller coupled to said third port of said interconnection circuit and to a memory interface, said memory interface comprising a data bus having first and second portions, a first chip select signal, and a second chip select signal;
wherein in response to said first memory access request, said memory access controller performs a first burst access using both said first and second portions of said data bus and both said first and second chip select signals; and
wherein in response to said second memory access request, said memory access controller performs a second burst access using a selected one of said first and second portions of said data bus and a corresponding one of said first and second chip select signals.

16. The data processor of claim 15, wherein said first memory accessing agent comprises a central processing unit core and a cache.

17. The data processor of claim 16, wherein said first size comprises 512 bits.

18. The data processor of claim 15, wherein said second memory accessing agent comprises a graphics processing unit (GPU).

19. The data processor of claim 18, wherein said wherein said second size comprises 256 bits.

20. The data processor of claim 15, wherein said first memory accessing agent comprises a plurality of central processing unit cores and a cache shared by each of said plurality of central processing unit cores.

21. The data processor of claim 15, wherein said memory access controller comprises:
a memory controller having a first port coupled to said interconnection circuit, and a second port;
a dynamic random access memory (DRAM) controller having a first port coupled to said second port of said memory controller, and a second port; and
a first physical interface circuit having a first port coupled to said second port of said DRAM controller, and a second port coupled to said memory interface.

22. The data processor of claim 21, wherein:
said DRAM controller further has a third port; and
said memory access controller further comprises a second physical interface circuit having a first port coupled to said third port of said DRAM controller, and a second port coupled to said memory interface.

23. The data processor of claim 15, wherein:
the data processor further comprises a plurality of input/output controllers for transferring data between the data processor and external agents; and
said interconnecting circuit comprises:
a host bridge coupled to said first and second ports of said interconnection circuit and having an internal port; and
a crossbar having a first port coupled to said internal port of said host bridge, a second port forming said third port of said interconnection circuit, and a plurality of further ports coupled to respective ones of said plurality of input/output controllers.

24. A method for accessing memory comprising:
providing a first memory access request having a first size;
providing a second memory access request having a second size;
performing, in response to said first memory access request, a first burst access using both first and second portions of a data bus and both first and second chip select signals; and
performing, in response to said second memory access request, a second burst access using a selected one of said first and second portions of said data bus and a corresponding one of said first and second chip select signals.

25. The method of claim 24, wherein said providing said first memory access request having said first size comprises providing said first memory access request in response to a cache miss.

26. The method of claim 24, wherein said providing said second memory access request having said second size comprises providing said second memory access request in response to a graphics access.

27. The method of claim 24, wherein said performing said first burst comprises performing said first burst access to a first rank of a memory.

28. The method of claim 27, wherein said performing said second burst access comprises performing said second burst access to said first rank of a memory.
